(19) United States
(12) Patent Application Publication
(10) Pub. No.: US 2026/0343985 A1
(43) Pub. Date: Oct. 29, 2026

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Feng-Ming Chang, Taitung City (TW); Kao-Ting Lai, Hsinchu City (TW); Yu-Jie Ye, Hsinchu City (TW); Yen-Cheng Lai, Tainan City (TW)

(21) Appl. No.: 19/732,278

(22) Filed: Jul. 6, 2026

Related U.S. Application Data
(63) Continuation of application No. 18/884,648, filed on Sep. 13, 2024.
(60) Provisional application No. 63/655,670, filed on Jun. 4, 2024.

(51) Int. Cl. H10D 64/01; H10D 30/01; H10D 30/43; H10D 30/67; H10D 62/10

(52) U.S. Cl. CPC H10D 64/017; H10D 30/014; H10D 30/43; H10D 30/6735; H10D 30/6757; H10D 62/121; H10D 64/021

(57) ABSTRACT

A method of forming a semiconductor device includes: forming a fin structure protruding above a substrate, where the fin structure includes a fin and includes layers of a first semiconductor material interleaved with layers of a second semiconductor material; forming a dummy gate dielectric over the fin structure; forming a dummy gate over the dummy gate dielectric, where the dummy gate dielectric extends beyond sidewalls of the dummy gate; forming a gate spacer along a sidewall of the dummy gate and on the dummy gate dielectric; forming a source/drain opening in the fin structure; replacing the first semiconductor material disposed under the dummy gate with a sacrificial material; forming a source/drain region in the source/drain opening; performing a first etching process and a second etching process to remove the dummy gate and the dummy gate dielectric, respectively; and after performing the second etching process, removing the sacrificial material.

### CROSS-REFERENCE TO RELATED APPLICATIONS

This application is a continuation of U.S. Patent Application No. 18/884,648, filed Sept. 13, 2024 and entitled "Nanostructure Field-Effect Transistor Device and Methods of Forming," which claims priority to U.S. Provisional Patent Application No. 63/655,670, filed Jun. 4, 2024 and entitled "Device Structure with Dummy Dielectric Layer for Disposal Oxide Interposer (DOI) Process," which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, 15C, 15D, 16A, and 16B, are cross-sectional views of a nanostructure field-effect transistor (NSFET) device at various stages of manufacturing, in accordance with an embodiment.

FIG. 17 illustrates a cross-sectional view of an NSFET device, in another embodiment.

FIG. 18 illustrates a cross-sectional view of an NSFET device, in another embodiment.

FIG. 19 illustrates a cross-sectional view of an NSFET device, in another embodiment.

FIG. 20 illustrates a cross-sectional view of an NSFET device, in yet another embodiment.

FIGS. 21A and 21B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

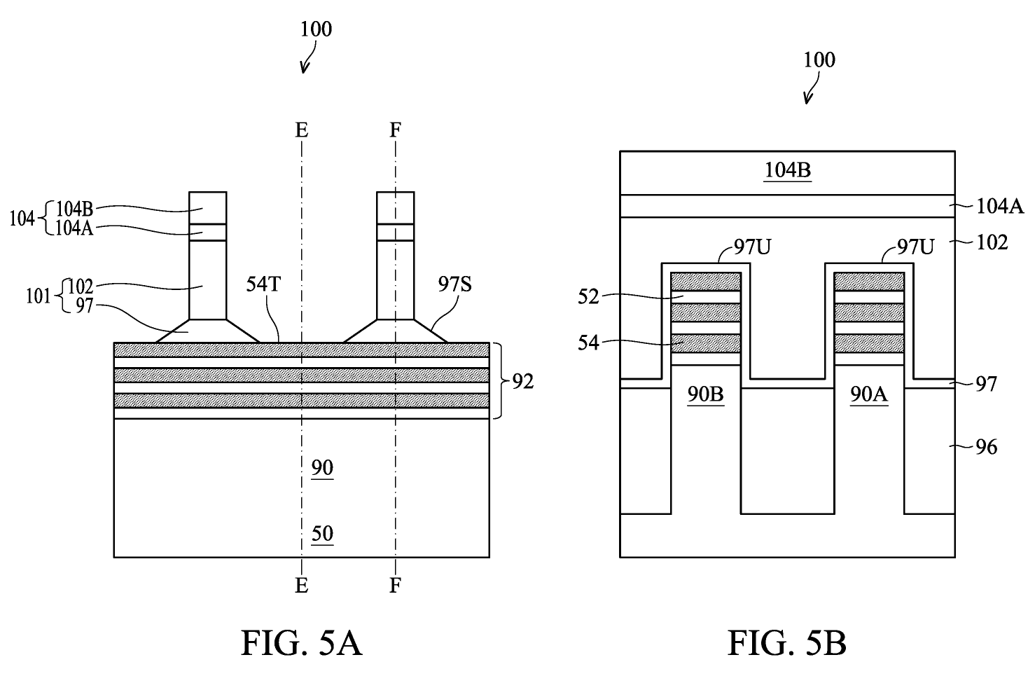

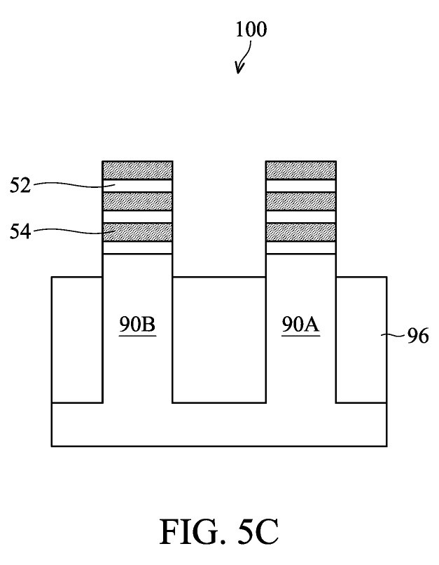

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIGS. 5A – 5C) illustrate different views of the NSFET device at the same stage of processing.

In accordance with some embodiments, disposable oxide interposers (DOIs) are used in the fabrication of a nanostructure field-effect transistor (NSFET) device. Dummy gate structures are formed, then replaced by replacement gate structures. The dummy gate dielectric of the dummy gate structures is formed of one or more layers of dielectric materials that are more etch-resistant (e.g., having lower etch rate) than silicon oxide, such as silicon oxycarbide, silicon oxynitride, silicon carbonitride, silicon oxycarbonitride, or a high-K dielectric material. The dummy gate dielectric extends beyond sidewalls of the dummy gate structures, such that gate spacers are formed along sidewalls of the dummy gate structures and on the dummy gate dielectric. In the subsequent replacement gate process, portions of the dummy gate dielectric disposed between gate spacers are removed, and remaining portions of the dummy gate dielectric under the gate spacers form dielectric structures. The dielectric structures prevent or reduce the occurrence of metal gate extrusion and/or electrical short between source/drain regions and the replacement gate structures, thereby avoiding device failure and improving production yield.

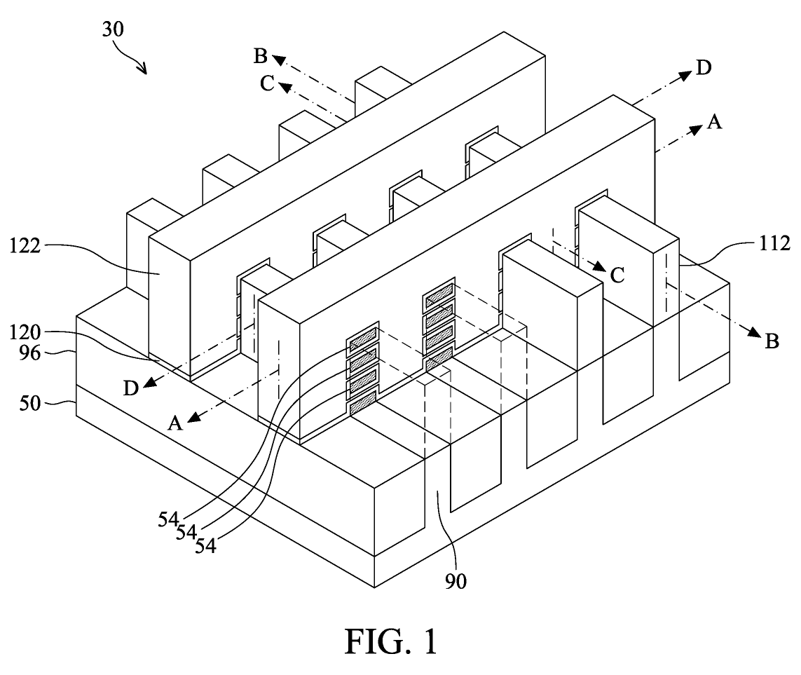

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device 30. Cross-section C-C is parallel to cross-section B-B and between two neighboring fins 90. Cross-section D-D is parallel to cross-section A-A and extends through source/drain regions 112 of the NSFET device 30. Subsequent figures may refer to these reference cross-sections for clarity.

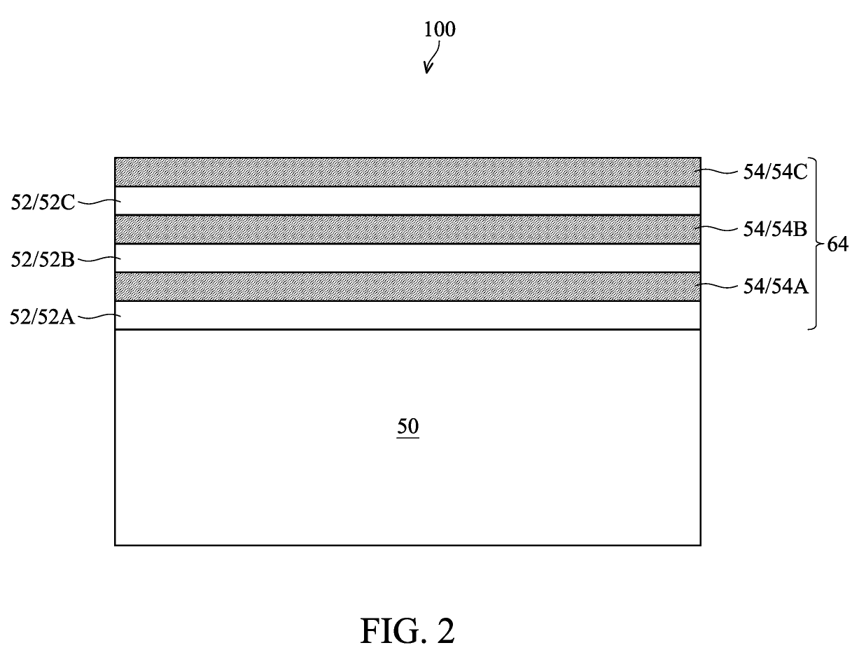

FIGS. 2, 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, 15C, 15D, 16A, and 16B, are cross-sectional views of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type or p-type FETs, and the first semiconductor material 52 is used as a sacrificial material that is removed later. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically:
(1) enabling a flow of the germanium precursor to the growth chamber when growing the first semiconductor material 52; and
(2) disabling the flow of the germanium precursor to the growth chamber when growing the second semiconductor material 54. The cyclical exposure may be repeated until a target number of layers is formed.

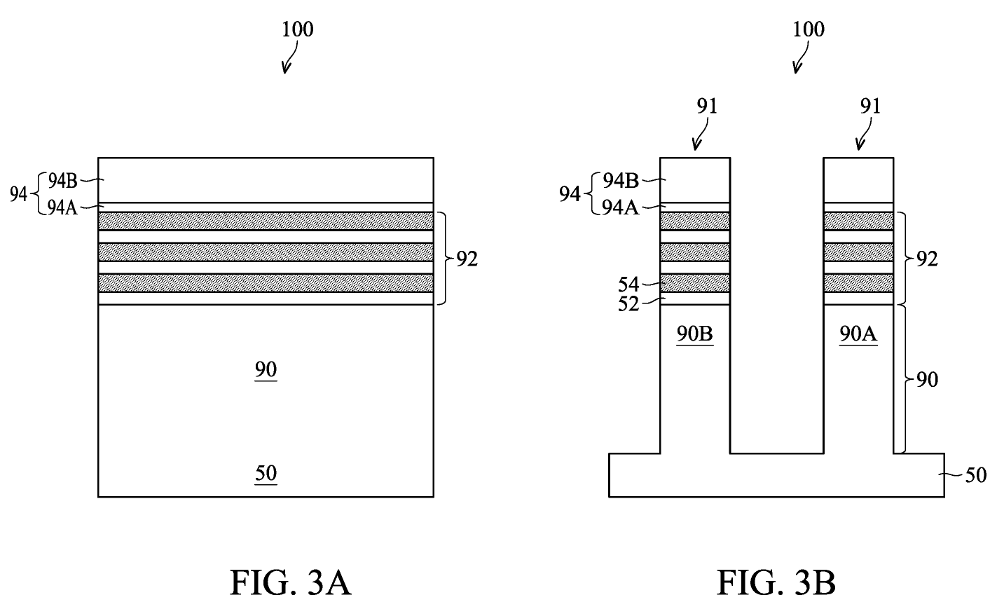

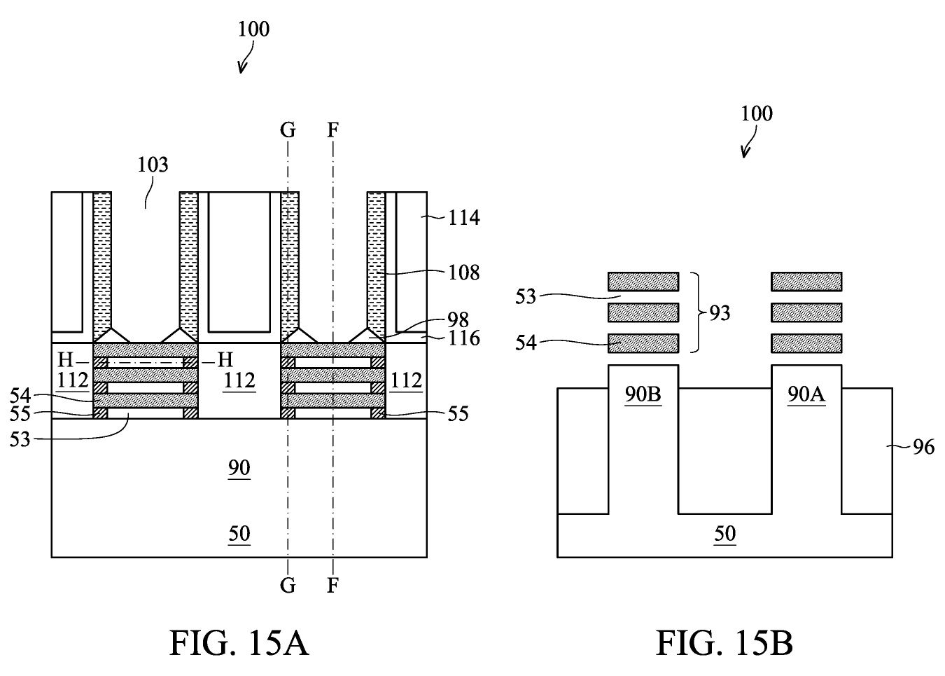

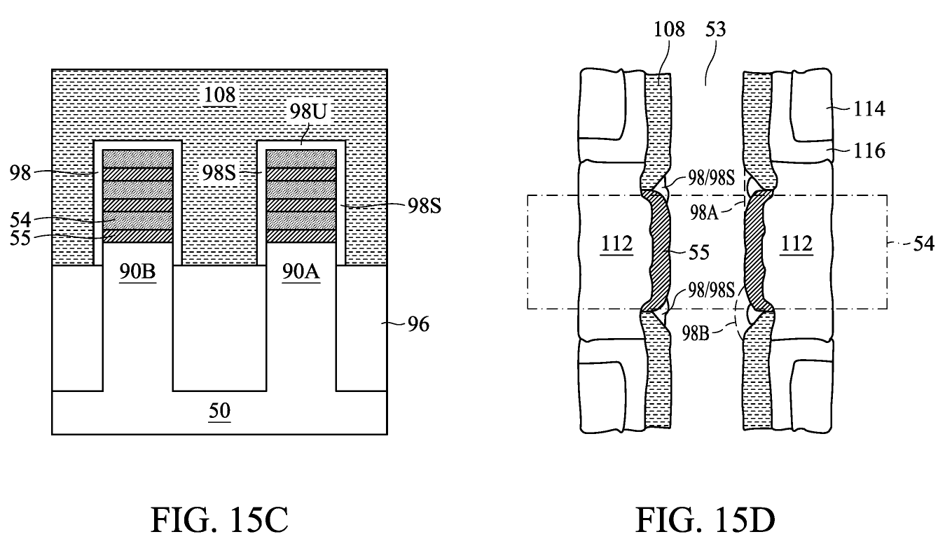

FIGS. 3A, 3B, 4A, 4B, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 14A, 14B, 15A, 15B, 15C, 15D, 16A, and 16B are cross-sectional views of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, and 16A are cross-sectional views along cross-section B-B in FIG. 1. FIGS. 3B, 4B, 5B, 6B, 7B, 8B, 9B, 10B, 11B, 12B, 13B, 14B, 15B, and 16B are cross-sectional views along cross-section A-A in FIG. 1. FIGS. 5C, 6C, 7C, 8C, 9C, 10C, 11C, and 12C are cross-sectional views along cross-section D-D in FIG. 1. FIGS. 15C and 15D are cross-sectional views along cross-sections G-G and H-H in FIG. 15A, respectively. The number of fins and the number of gate structures illustrated in the figures are merely a non-limiting example, it should be appreciated that other numbers of fins and other numbers of gate structures may also be formed.

In FIG. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned substrate 50 forms the fin 90, as illustrated in FIG. 3A and 3B. Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have straight sidewalls that are perpendicular to the upper surface of the substrate 50. In some embodiments, the fins 90 and the layer stacks 92 have sloped sidewalls (e.g., having trapezoidal cross-sections). The shapes of the fins 90 and the layer stacks 92 illustrated in FIG. 3B are merely non-limiting examples.

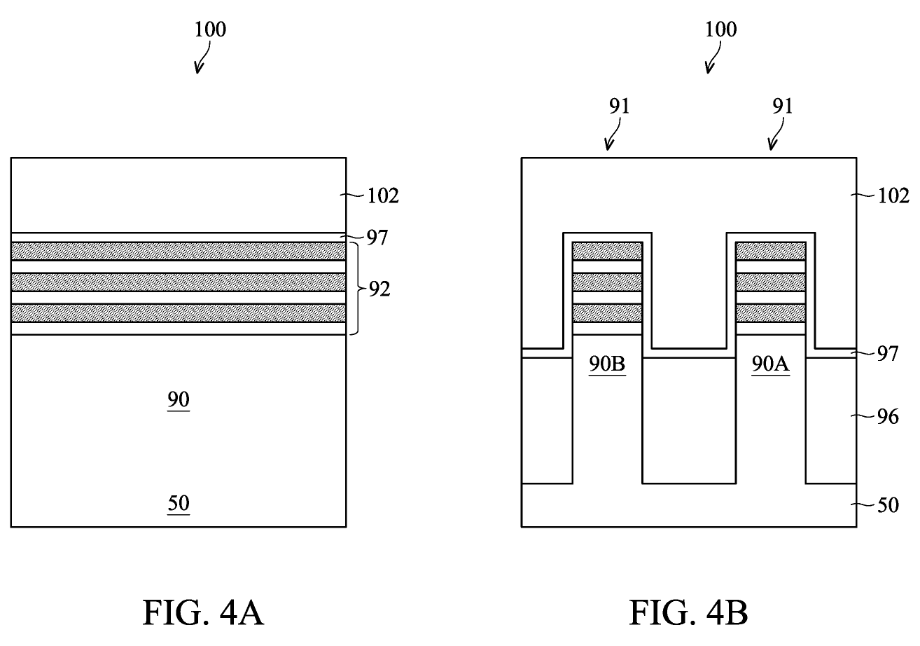

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96 using a suitable deposition method, such as CVD, atomic layer deposition (ALD), or the like. In some embodiments, the dummy dielectric layer 97 is silicon oxycarbide, silicon oxynitride, silicon carbonitride, or silicon oxycarbonitride. In some embodiments, the dummy dielectric layer 97 is a high-K dielectric material, and may include a metal oxide or a silicate of Hf, Al, Zr, La, Mg, Ba, Ti, or Pb, or combinations thereof. For example, aluminum oxide, hafnium oxide, or the like, may be used as the dummy dielectric layer 97. A thickness of the dummy dielectric layer 97 may be between about 0.5 nm and about 10 nm, as an example. Notably, the material for the dummy dielectric layer 97 is different from the commonly used material of silicon oxide for forming dummy gate dielectric, and is chosen to be different from the material of the subsequently formed disposable material 57 to provide etching selectivity and to prevent metal gate extrusion, details are discussed hereinafter.

Next, a dummy gate layer 102 is formed over the dummy dielectric layer 97. The dummy gate layer 102 may be deposited over the dummy dielectric layer 97 and then planarized, such as by a CMP. The dummy gate layer 102 may be, e.g., amorphous silicon, polycrystalline-silicon (polysilicon), poly-crystalline silicon-germanium (poly-SiGe), or the like. The dummy gate layer 102 may be deposited by physical vapor deposition (PVD), CVD, sputter deposition, or other techniques known and used in the art. The dummy gate layer 102 may be made of other materials that have a high etching selectivity from the STI regions 96.

Next, in FIGS. 5A–5C, masks 104 are formed over the dummy gate layer 102. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectric 97 are collectively referred to as dummy gate structures 101, in some embodiments.

FIGS. 5B and 5C illustrate cross-sectional views of the NSFET device 100 in FIG. 5A along cross-sections F-F and E-E in FIG. 5A, respectively. The cross-sections F-F and E-E correspond to cross-sections A-A and D-D in FIG. 1, respectively.

In the example of FIG. 5A, the dummy gate dielectric 97 extends beyond sidewalls of the overlying dummy gate 102. In other words, the dummy gate dielectric 97 underlying the dummy gate 102 is wider than the dummy gate 102. The larger width of the dummy gate dielectric 97 may result from the limited capability of the anisotropic etching process(es) (e.g., used for patterning the dummy gate layer 102 and the dummy dielectric layer 97) to reach the bottoms of the trenches between adjacent dummy gates 102, especially for trenches with high aspect ratios. In addition, the dummy gate dielectric 97 in center regions of the bottoms of the trenches may be easier to remove than the dummy gate dielectric 97 in edge regions (e.g., regions contacting the dummy gates 102) of the bottoms of the trenches. Note that in FIG. 5A (and some subsequent figures), the thickness of the dummy gate dielectric 97, as well as the width of the dummy gate dielectric 97, may be exaggerated to facilitate illustration of the details of subsequent processing.

As a non-limiting example, the dummy gate dielectric 97 under each dummy gate 102 in FIG. 5A is illustrated as having sloped sidewalls 97S and a trapezoidal cross-section. Note that the dummy gate dielectric 97 illustrated in FIG. 5A corresponds to upper portions 97U (see FIG. 5B) of the dummy gate dielectric 97, which upper portions 97U are disposed over the upper surfaces of the layer stacks 92.

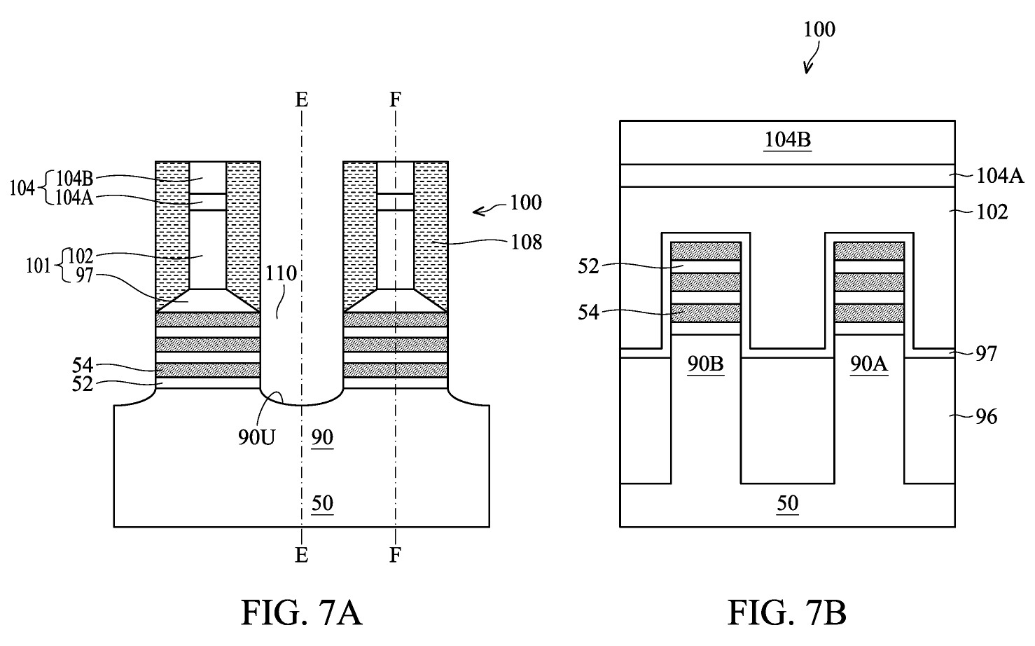

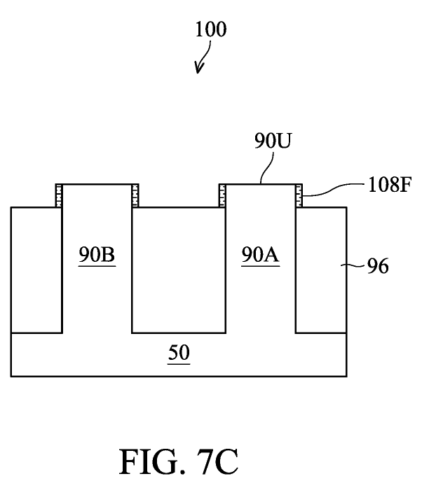

In some embodiments, the anisotropic etching process(es) used for forming the dummy gate 102 and the dummy gate dielectric 97 may also remove upper portions of the topmost layer of the second semiconductor material 54 in the layer stack 92, and therefore, regions of an upper surface 54T of the topmost layer of the second semiconductor material 54 uncovered (e.g., exposed) by the dummy gate dielectric 97 shown in FIG. 5A may be curved (e.g., concave). In other embodiments, after the anisotropic etching process(es), besides the dummy gate dielectric 97 shown in FIG. 5A, residual portions of the dummy dielectric layer may cover the upper surface 54T of the topmost layer of the second semiconductor material 54, which residual portions have a much smaller thickness than the dummy gate dielectric 97 shown in FIG. 5A. In a subsequent etching process performed to form source/drain openings 110 (see FIG. 7A), the residual portions of the dummy dielectric layer, if formed, are removed by the subsequent etching process.

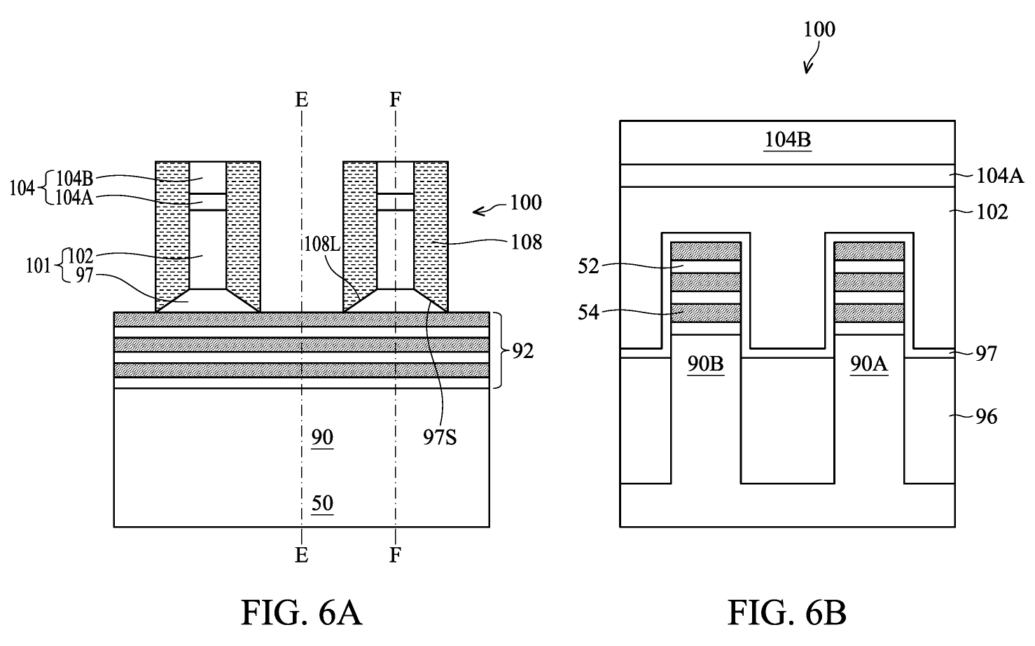

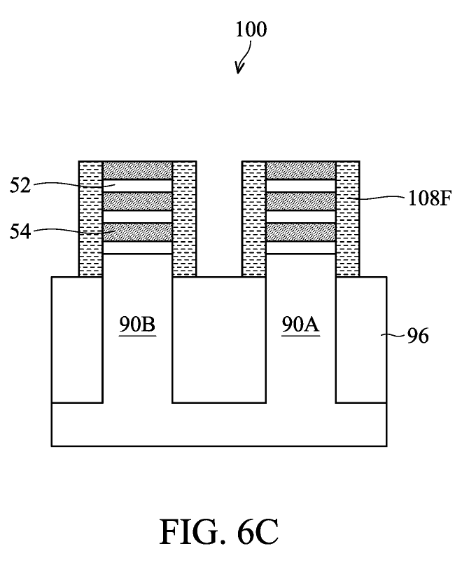

Next, in FIGS. 6A-6C, gate spacers 108 are formed along sidewalls of the dummy gate structures 101 and sidewalls of the masks 104. Notably, in the cross-sectional view of FIG. 6A, the gate spacers 108 are formed on the sloped sidewalls 97S of the dummy gate dielectric 97. In other words, the lower surface 108L of each gate spacer 108 contacts and extends along a respective sloped sidewall 97S of the underlying dummy gate dielectric 97.

In some embodiments, to form the gate spacers 108, a gate spacer layer is formed by conformally depositing an insulating material over the layer stacks 92, the STI regions 96, and the dummy gate structures 101. The insulating material may be silicon nitride, silicon carbonitride, a combination thereof, or the like. In some embodiments, the gate spacer layer includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

Next, the gate spacer layer is etched by an anisotropic etching process to form the gate spacers 108. The anisotropic etching process may remove horizontal portions of the gate spacer layer (e.g., portions over the STI regions 96 and the dummy gate structures 101), with remaining vertical portions of the gate spacer layer (e.g., portions along sidewalls of the dummy gate structures 101) forming the gate spacers 108. Remaining portions of the gate spacer layer along sidewalls of the fin structures may form fin spacers 108F, as illustrated in FIG. 6C.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, in FIGS. 7A-7C, openings 110 (which may also be referred to as recesses 110, or source/drain openings 110) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask. The openings 110 expose upper surfaces 90U of the fins 90, and expose portions of the first semiconductor material 52 and portions of the second semiconductor material 54 that are disposed under the dummy gate structures 101. In the example of FIG. 7C, the height of the fin spacers 108F is reduced by the anisotropic etching process to form the openings 110. In other embodiments, the height of the fin spacers 108F is substantially unchanged by the anisotropic etching process to form the openings 110. In addition, in FIG. 7C, upper surfaces 90U of the fins 90 are illustrated as being level with the upper surfaces of the fin spacers 108F. In other embodiments, the upper surfaces 90U of the fins 90 extend closer to the substrate 50 than the upper surfaces of the fin spacers 108F. These and other variations are fully intended to be included within the scope of the present disclosure.

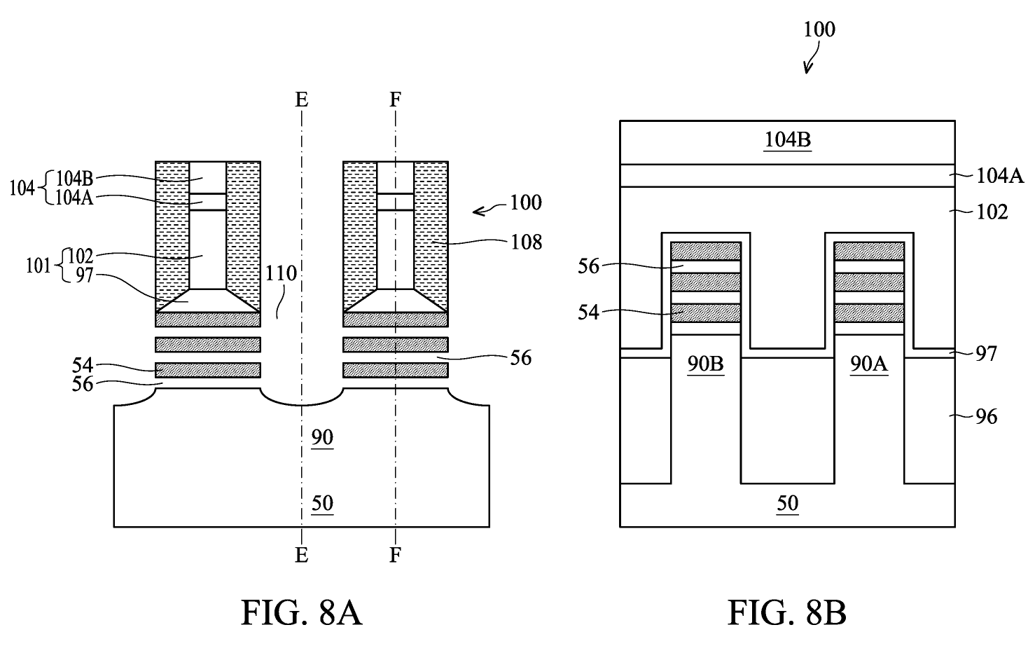

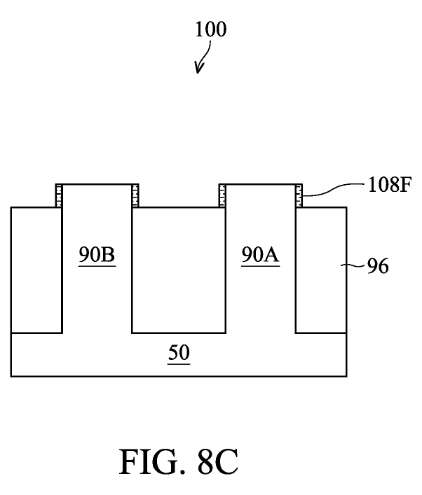

Next, in FIGS. 8A-8C, the first semiconductor material 52 under the dummy gate structures 101 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, the gate spacers 108, and the STI regions 96 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

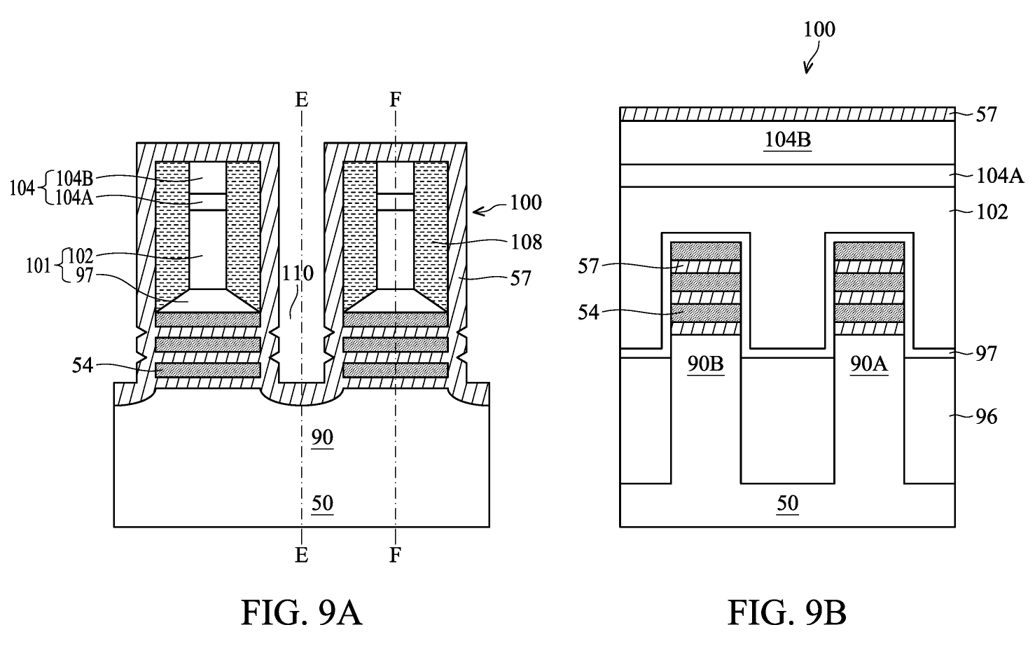

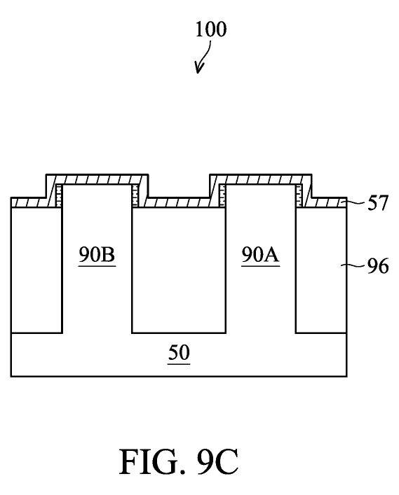

Next, in FIGS. 9A-9C, a disposable material 57 (may also be referred to as a sacrificial material 57) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material. In some embodiments, the disposable material 57 includes one or more layers of silicon oxide (SiO), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the specific requirements of the semiconductor device being fabricated and the desired electrical and physical properties of the final product.

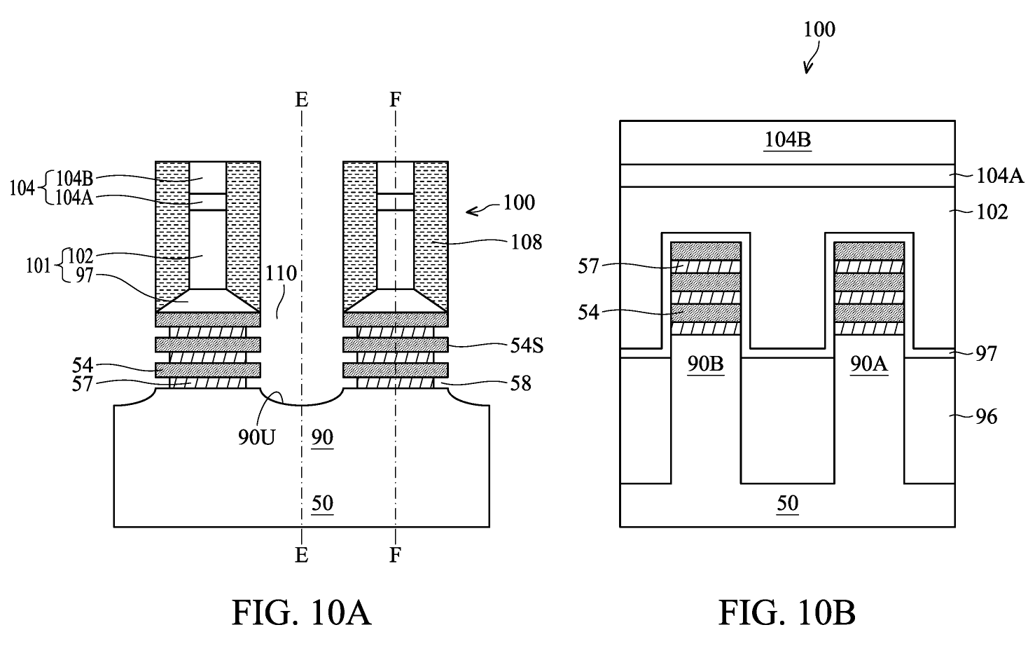

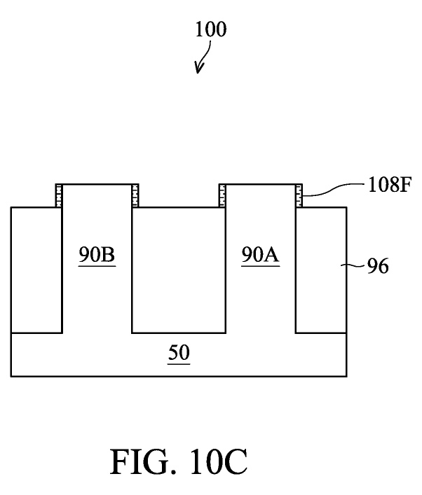

Next, in FIGS. 10A-10C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, or between the fins 90 and a lowermost layer of the second semiconductor material 54, may be referred to as disposable oxide interposers (DOIs). In a subsequent sheet formation process, the DOIs are selectively removed to release the layers of the second semiconductor material 54 to form nanostructures 54 (e.g., nanosheets, or nanowires). The disclosed process for forming nanostructures, which includes replacement of the first semiconductor material 52 by the disposable material 57, and the subsequent removal of the disposable material 57, may be referred to as a DOI process.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., silicon oxide) of the DOIs provide excellent etching selectivity (e.g., higher than 10000) from the material (e.g. Si) of the second semiconductor material 54, thus allowing selective removal of the DOIs in the sheet formation process with little or no damage to the nanostructures 54.

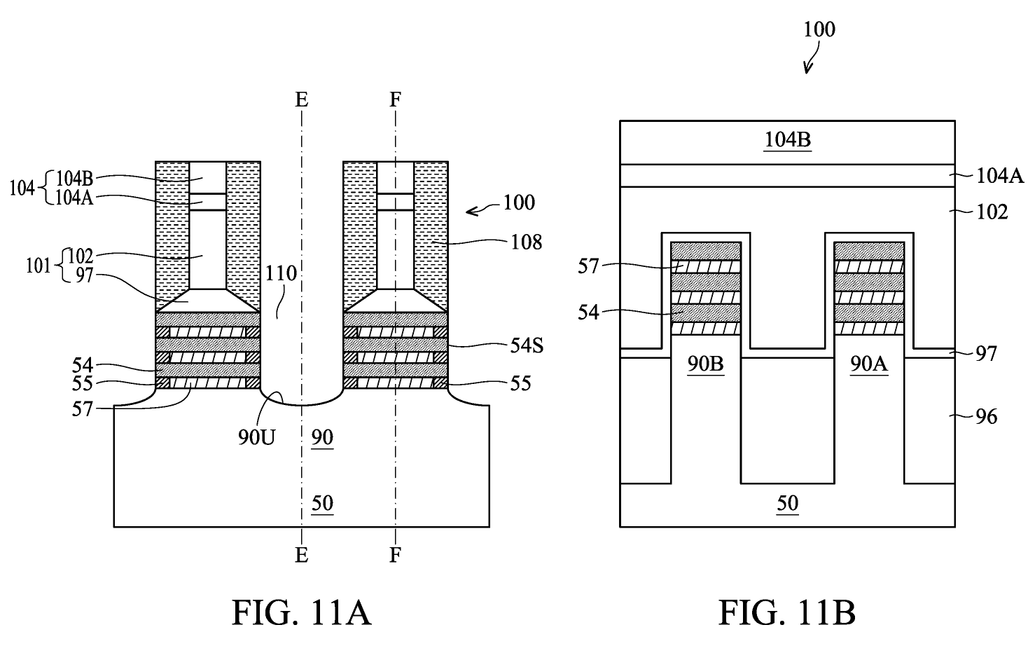

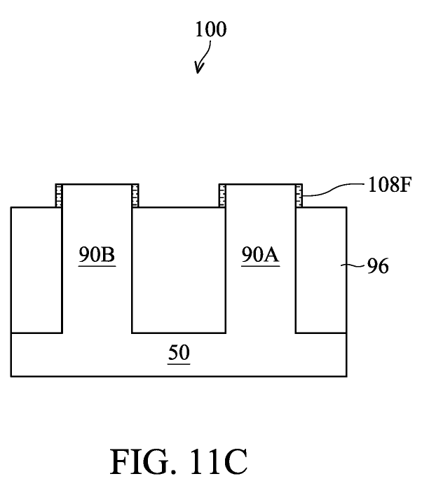

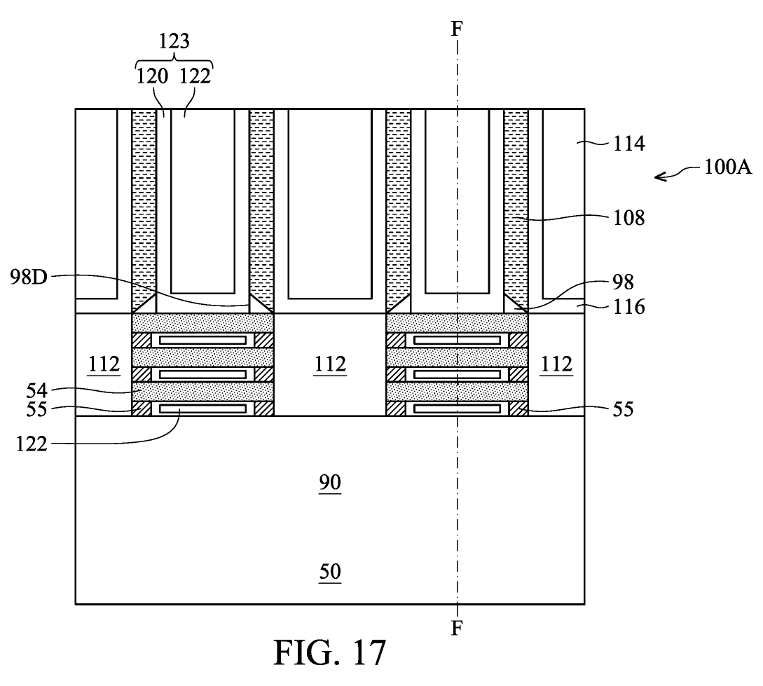

Next, in FIGS. 11A-11C, inner spacers 55 are formed in the sidewall recesses 58. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58) form inner spacers 55. In the example of FIG. 17, sidewalls of the inner spacers 55 exposed by the openings 110 are flush with sidewalls 54S of the second semiconductor material 54. This is, of course, merely a non-limiting example. The sidewalls of the inner spacers 55 may protrude beyond the sidewalls 54S into the openings 110, or may be recessed from the sidewalls 54S.

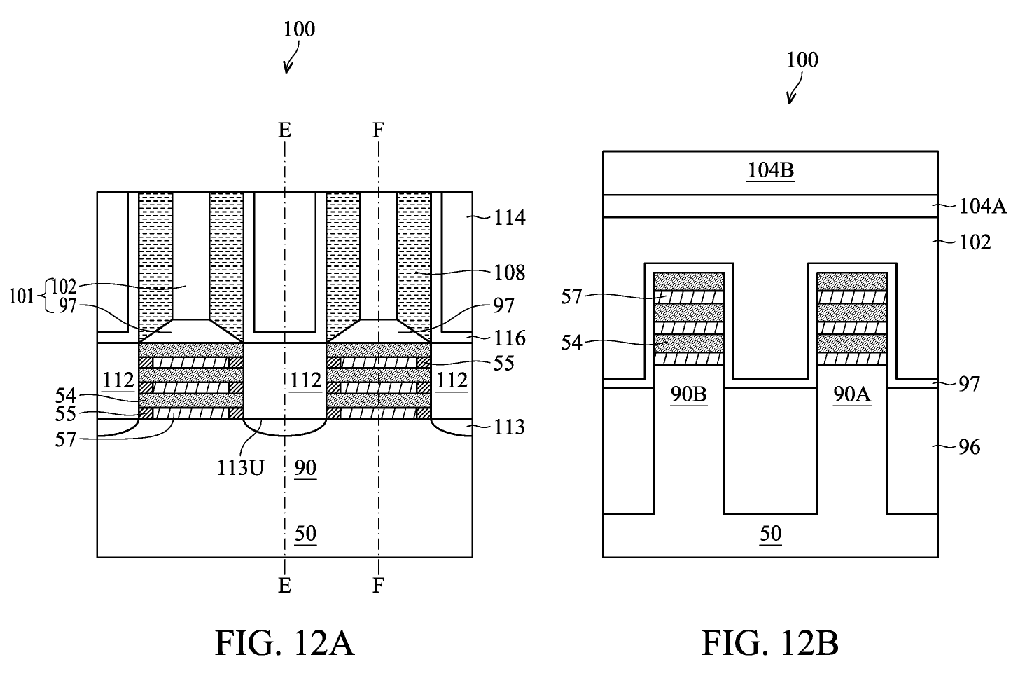

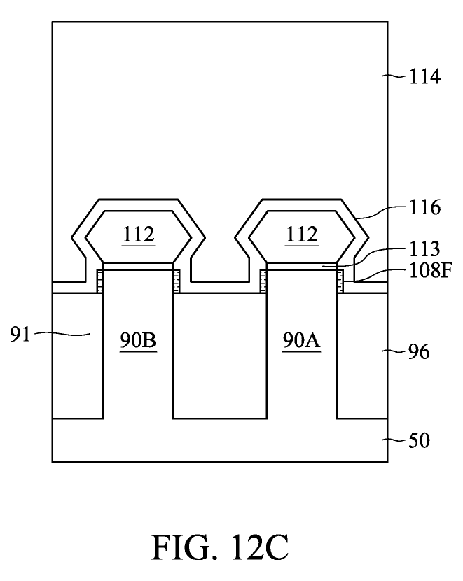

Next, in FIGS. 12A-12C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed, as illustrated in FIG. 12C. In other embodiments, these facets cause adjacent epitaxial source/drain regions 112 to merge.

In some embodiments, before the source/drain regions 112 are formed, a semiconductor layer 113 is formed at the bottoms of the openings 110. The semiconductor layer 113 may comprise the same material (e.g., silicon) as the substrate 50, and may be formed by epitaxially growing the semiconductor material (e.g., silicon) at the bottoms of the openings 110. In the illustrated embodiment, the semiconductor layer 113 is an un-doped epitaxial material, such as a layer of un-doped epitaxial silicon. In some embodiments, the upper surface 113U of the semiconductor layer 113 is lower (e.g., closer to the substrate 50) than the lower surface of the lowermost layer of the second semiconductor material 54 in the layer stack 92, in order to avoid blocking electrical connection between the subsequently formed nanostructures 54 and the source/drain regions 112. The semiconductor layer 113 may advantageously prevent or reduce body leakage (e.g., leakage current between the source/drain regions 112 and the substrate 50), and in addition, may prevent or reduce leakage current flowing between two adjacent source/drain regions 112 through a leakage path along an upper surface of the fin 90.

Still referring to FIGS. 12A-12C, next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

After the CESL 116 and the first ILD 114 are formed, a planarization process, such as CMP, is performed to remove the CESL 116 and the first ILD 114 from the upper surfaces of the dummy gate structures 101. The planarization process also removes the masks 104, such that after the planarization process is finished, the upper surfaces of the dummy gates 102 are exposed. As illustrated in FIG. 12A, after the planarization process is finished, the dummy gate structures 101, the gate spacers 108, the CESL 116, and the first ILD 114 have a coplanar upper surface.

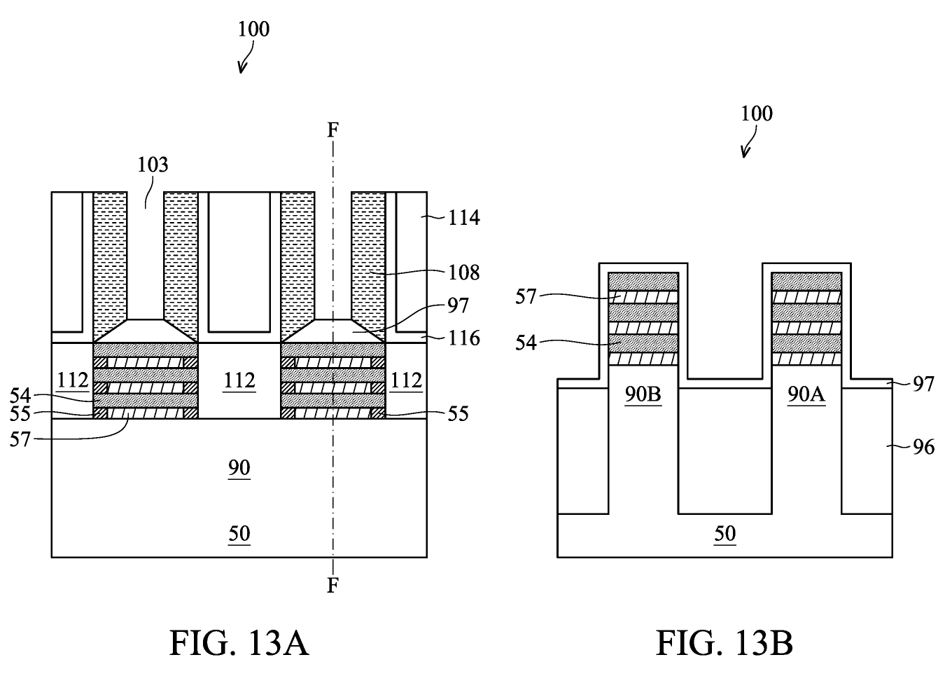

FIGS. 13A, 13B, 14A, 14B, 15A, 15B, 15C, 15D, 16A, and 16B illustrate a replacement gate process performed subsequently, where the dummy gate structures 101 are removed and replaced by replacement gate structures 123 (e.g., metal gate structures). The cross-sectional views corresponding to FIG. 12C are not illustrated for the replacement gate process, because such cross-sectional views remain the same as FIG. 12C, in some embodiments.

Next, in FIGS. 13A and 13B, the dummy gates 102 are removed in an etching step(s), so that recesses 103 (may also be referred to as gate trenches 103) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the dummy gate dielectric 97, the first ILD 114, and the gate spacers 108. As another example, a wet etching process using a suitable etchant (e.g., ammonia) may be performed to selectively remove the dummy gates 102. After the dummy gates 102 are removed, the dummy gate dielectric 97 is exposed at the bottoms of the recesses 103.

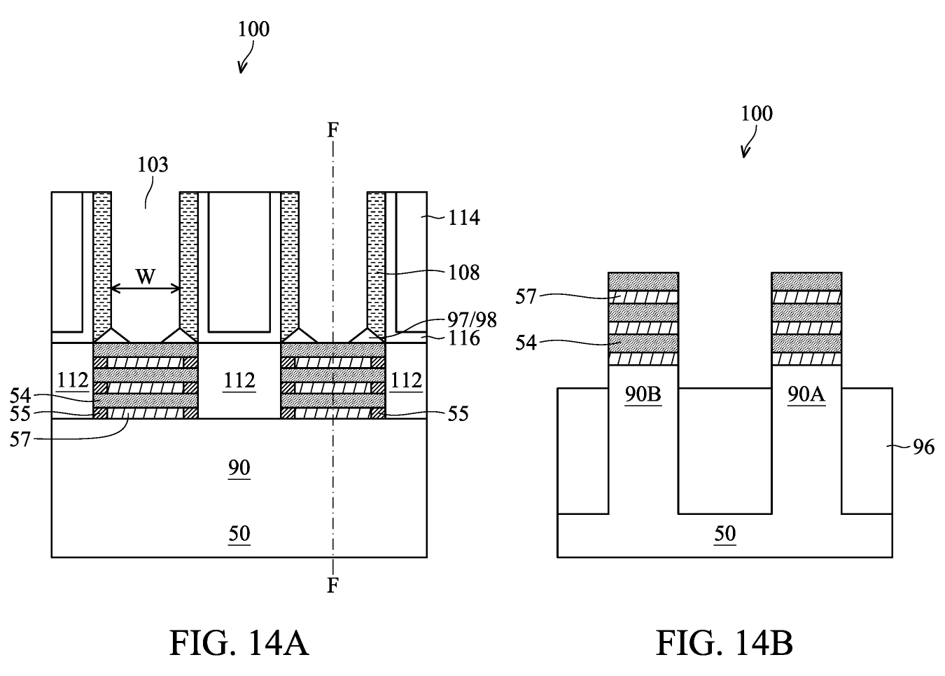

Next, in FIGS. 14A and 14B, a trimming process (also referred to as a gate spacer trimming process) is performed to reduce the thicknesses of the gate spacers 108, such that the widths W of the recesses 103 are increased compared with those of the recesses 103 in FIG. 13A. The increased widths W of the recesses 103 allow easier filling of materials of the subsequently formed replacement gate structures 123, and reduces the electrical resistance of the replacement gate structures 123.

The trimming process also etches the dummy gate dielectric 97. In the illustrated embodiment, the center portions of the dummy gate dielectric 97, which are exposed at the bottoms of the recesses 103 in FIG. 13A, are removed by the trimming process. In addition, as the gate spacers 108 are trimmed (e.g., thinned) by the trimming process, portions of the dummy gate dielectric 97, which are previously disposed directly under the gate spacers 108, are exposed and etched by the trimming process. After the trimming process is finished, portions of the dummy gate dielectric 97 remain, and are disposed between the gate spacers 108 and the second semiconductor material 54, as illustrated in FIG. 14A. For ease of discussion, these remaining portions of the dummy gate dielectric 97 are referred to as dielectric structures 98 hereinafter. In the cross-sectional view of FIG. 14A, the dielectric structures 98 are illustrated to have triangular-shaped cross-sections as a non-limiting example. Each dielectric structure 98 in FIG. 14A has two sloped sidewalls that intersect at a sidewall of a respective (trimmed) gate spacer 108 facing the recess 103.

In some embodiments, the trimming process is performed in two steps. In the first step, the gate spacers 108 are treated by a plasma process. The plasma process is performed using a gas source comprising oxygen. In some embodiments, the gate spacers 108 are formed of silicon oxycarbonitride (e.g., SiOCN), and the plasma process replaces carbon and nitrogen elements in the gate spacers 108 with oxygen elements in the plasma of the gas source, thereby increasing the concentration (e.g., molecular concentration) of oxygen in the gate spacers 108. For example, the bonds between silicon and carbon, and the bonds between silicon and nitrogen, are broken and replaced by bonds between silicon and oxygen. Therefore, the plasma process changes the chemical composition of the gate spacers 108, and makes the properties (e.g., densities, etch rate) of the gate spacers 108 more like an oxide (e.g., silicon oxide) in preparation for the etching process performed in the second step, in some embodiments. In some embodiments, due to the treatment by the plasma process, exterior portions (e.g., exposed portions) of the gate spacers 108 have higher concentrations of oxygen than interior portions (e.g., un-exposed portions) of the gate spacers 108. Next, in the second step, an etching process is performed to trim (e.g., thin) the gate spacers 108. The etching process may be a dry etching process performed using a gas source comprising HF and NH₃, as an example. By making the gate spacers 108 more oxide-like, the etching process may remove the exterior portions of the gate spacers 108 more efficiently to reduce processing time.

In some embodiments, the trimming process is omitted. For example, after the dummy gates 102 are removed by the processing of FIGS. 13A and 13B, a suitable etching process may be performed, e.g., using an etchant selective to the dummy gate dielectric 97. After the etching process, remaining portions of the dummy gate dielectric 97 form dielectric structures 98 disposed between the gate spacers 108 and the second semiconductor material 54, similar to FIGS. 14A and 14B. Details are not repeated. Discussion hereinafter uses the example where the trimming process is performed, with the understanding that the trimming process may be omitted.

Next, in FIGS. 15A and 15B, the disposable material 57 is removed to release the second semiconductor material 54, which may be referred to as the sheet formation process. After the disposable material 57 is removed, the second semiconductor material 54 (e.g., portions underlying the dummy gate structures 101 before the dummy gate structures 101 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100. As illustrated in FIGS. 15A and 15B, gaps 53 (e.g., empty spaces) are formed between the nanostructures 54 and between the lowermost nanostructure 54 and the fins 90 by the removal of the disposable material 57. In some embodiments, the nanostructures 54 are nanosheets or nanowires, depending on, e.g., the dimensions (e.g., size and/or aspect ratio) of the nanostructures 54.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57.

In some embodiments, a high etching selectivity of 10000 or more is achieved between the disposable material 57 and the second semiconductor material 54. In other words, the disposable material 57 is removed by the isotropic etching process at an etch rate 10000 times or more than the etch rate of the second semiconductor material 54. As a result, the etching process (e.g., the sheet formation process) used to remove the disposable material 57 causes little or no damage to the nanostructures 54. In addition, since the dielectric structures 98 are formed of a different material from the disposable material 57, the selective etching process used to remove the disposable material 57 causes little to no damage to the dielectric structures 98.

During the sheet formation process, the disclosed dielectric structures 98 prevents or reduces the occurrence of the so-called “metal gate extrusion” and/or electrical short between the source/drain regions 112 and the subsequently formed replacement gate structures 123. To appreciate the advantage, consider a reference design where the dummy gate dielectric 97 is formed of silicon oxide. The resulting dielectric structure 98 of the reference design is also formed of silicon oxide. In embodiments where the disposable material 57 is formed of silicon oxide, the selective etching performed during the sheet formation process to remove the disposable material 57 also removes the dielectric structures 98, and may even expose the source/drain regions 112. The subsequently formed replacement gate structures 123 may fill the spaces left by the removed dielectric structures 98, thereby producing protrusions that extend toward the source/drain regions 112. The protrusions of the replacement gate structures may be referred to as metal gate extrusion. Metal gate extrusion may increase the leakage current between the replacement gate structures 123 and the source/drain regions 112. If the source/drain regions 112 are exposed during the sheet formation process, electrical short between the source/drain regions 112 and the replacement gate structures 123 may occur, thereby causing device failure. The current disclosure, by forming the dielectric structures 98 with a material different from the disposable material 57 and having higher etching resistance (e.g., lower etch rate) for the sheet formation process, prevents or reduces the occurrence of metal gate extrusion and/or electrical short between the replacement gate structures 123 and the source/drain regions 112, thus improving device performance and production yield.

FIG. 15C illustrates a cross-section view of the NSFET device 100 along cross-section G-G of FIG. 15A. The cross-section G-G cuts vertically through the gate spacer 108, the dielectric structure 98, the inner spacers 55, the nanostructures 54, the fin 90 and the substrate 50. As illustrated in FIG. 15C, the dielectric structure 98 is disposed between the gate spacer 108 and nanostructures 54. In particular, the dielectric structure 98 surrounds the nanostructures 54 and the inner spacers 55. Upper portions 98U of the dielectric structures 98, which are disposed over the upper surfaces of the topmost nanostructures 54, correspond to the dielectric structures 98 shown in FIG. 15A.

FIG. 15D illustrates a cross-section view of the NSFET device 100 along cross-section H-H of FIG. 15A. The cross-section H-H cuts horizontally across inner spacers 55 and a gap 53 between nanostructures 54. Therefore, FIG. 15D is also a top view of a portion of the NSFET device 100 in FIG. 15A. The dashed lines in FIG. 15D illustrate the boundaries (e.g., sidewalls) of an overlying or underlying nanostructure 54. In FIG. 15D, the dielectric structures 98 contacting a same inner spacer 55 correspond to sidewall portions 98S of one of the dielectric structures 98 in FIG. 15C. In the top view of FIG. 15D, each of the dielectric structure 98 is disposed between an inner spacer 55 and a corresponding gate spacer 108. The sidewall of the dielectric structure 98 facing the gap 53 (which is filled by the subsequently formed replacement gate structure 123) is recessed from the sidewall of the respective gate spacer 108. This is, of course, merely a non-limiting example. The sidewall of the dielectric structure 98 facing the gap 53 may be flush with, or protrude from, the sidewall of the respective gate spacer 108, as illustrated by the dashed line 98A and 98B, respectively. These and other variations are fully intended to be included within the scope of the present disclosure.

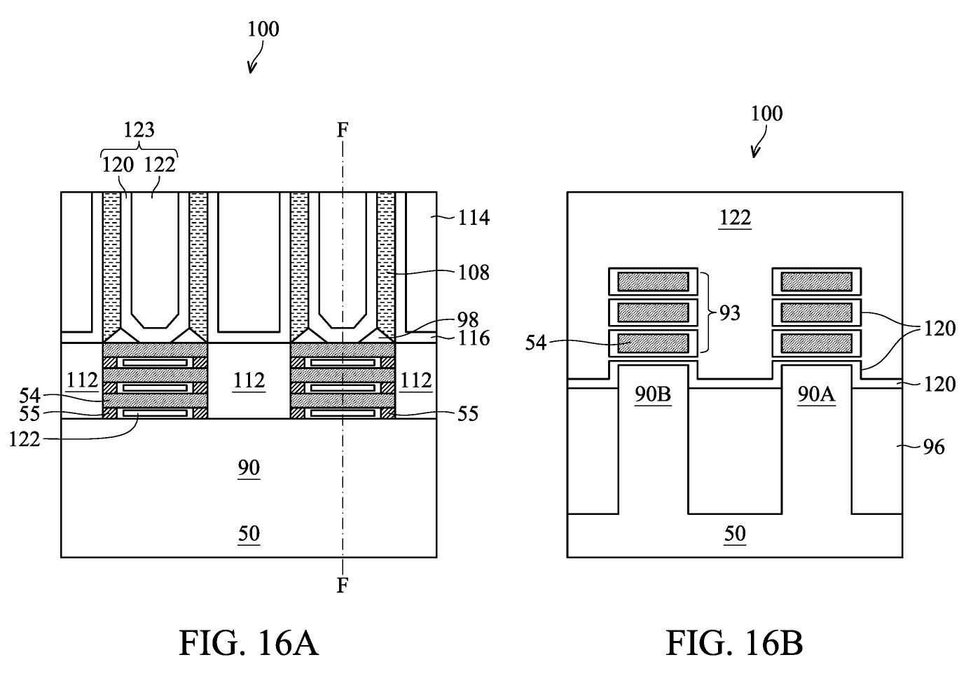

Next, in FIGS. 16A-16B, gate dielectric layers 120 and gate electrodes 122 are formed to form replacement gate structures 123. In some embodiments, a gate dielectric material 120 is deposited conformally in the recesses 103, such as on the top surfaces and the sidewalls of the fins 90, and on sidewalls of the gate spacers 108. The gate dielectric material 120 may also be formed on the top surface of the first ILD 114. Notably, the gate dielectric material 120 is formed to wrap around the nanostructures 54, and is formed to extend along sidewalls of the dielectric structures 98. In accordance with some embodiments, the gate dielectric material 120 comprises silicon oxide, silicon nitride, or multilayers thereof. In some embodiments, the gate dielectric material 120 comprises a high-K dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, and fill the remaining portions of the recesses 103. The gate electrode material may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Additional processing steps may be performed to complete the fabrication of the NSFET device 100, as skilled artisans readily appreciate. For example, a second ILD may be formed over the first ILD 114. Gate contact plugs and source/drain contact plugs may be formed to extend through the second ILD and/or the first ILD 114 to be electrically coupled to the gate structures 123 and the source/drain regions 112. Next, an interconnect structure, which includes multiple dielectric layers and conductive features (e.g., vias and conductive lines) formed in the multiple dielectric layers, is formed to interconnect the underlying electrical components (e.g., NSFETs) to form functional circuits. Next, external connectors (e.g., copper pillars, conductive bumps) may be formed to be electrically coupled to the interconnect structure to provide electrical connection to other electrical devices. Dicing may be performed to separate multiple NSFET devices into separate individual devices. Details are not discussed here.

FIG. 17 illustrates a cross-sectional view of an NSFET device 100A, in another embodiment. The NSFET device 100A is similar to the NSFET device 100, and may be formed by the same or similar formation process for the NSFET device 100. The NSFET device 100A, however, has a different sidewall profile for the dielectric structures 98. In particular, the sidewalls 98C of the dielectric structures 98 facing the replacement gate structure 123 are flush with sidewalls of respective gate spacers 108. In contrast, the sidewalls of the dielectric structures 98 of the NSFET device 100 (see FIG. 16A) facing the replacement gate structures 123 protrude from the sidewalls of respective gate spacers 108. The different sidewall profiles for the dielectric structures 98 may result from different choices of material(s) for the dielectric structures 98, and/or the different etching conditions of the etching process(es) the dielectric structures 98 are subjected to.

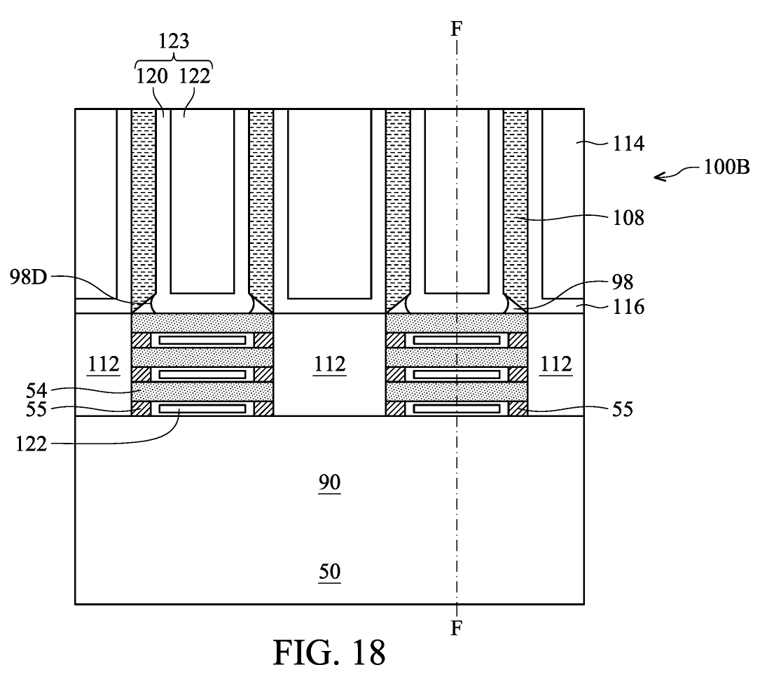

FIG. 18 illustrates a cross-sectional view of an NSFET device 100B, in another embodiment. The NSFET device 100B is similar to the NSFET device 100, and may be formed by the same or similar formation process for the NSFET device 100. The NSFET device 100B, however, has a different sidewall profile for the dielectric structures 98. In particular, the sidewalls 98D of the dielectric structures 98 facing the replacement gate structures 123 are recessed from sidewalls of respective gate spacers 108, and may be curved (e.g., concave) sidewalls. As a result, the replacement gate structures 123 have protrusions that extend below the gate spacers 108, and the protrusions may have rounded (e.g., curved) surfaces contacting the dielectric structures 98.

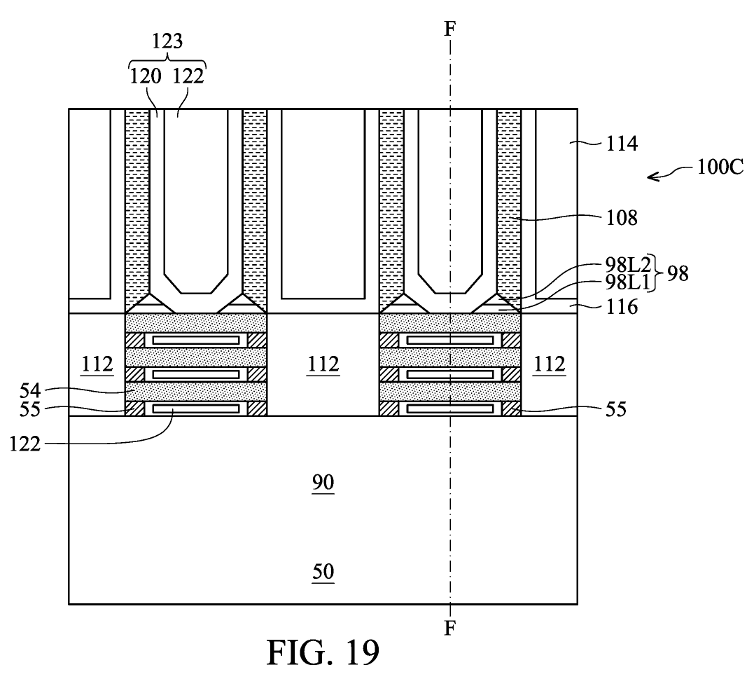

FIG. 19 illustrates a cross-sectional view of an NSFET device 100C, in another embodiment. The NSFET device 100C is similar to the NSFET device 100, and may be formed by the same or similar formation process for the NSFET device 100. The NSFET device 100C, however, has a multi-layered structure for the dielectric structures 98. For example, in the processing step of FIGS. 4A and 4B, the dummy dielectric layer 97 is formed to have a bi-layered structure, such as by forming a layer of a first dielectric material and a layer of a second dielectric material successively on the layer stack 92. The first dielectric material and the second dielectric material are different materials, and may be chosen from the list of materials discussed above for the dummy dielectric layer 97. After the trimming process of the gate spacers 108 in FIGS. 14A and 14B, the remaining portions of the dummy dielectric layer 97 form the dielectric structures 98 of the NSFET device 100C.

As illustrated in FIG. 19, the dielectric structures 98 has a multi-layered structure (e.g., bi-layered structure). The dielectric structures 98 in FIG. 19 have two layers of dielectric materials: a layer 98L1 of a first dielectric material, and a layer 98L2 of a second dielectric material different from the first dielectric material. Each of the dielectric structures 98 in FIG. 19 has two sloped sidewalls that intersect at a sidewall of a respective gate spacer 108. A first sloped sidewall contacts and extends along a lower surface of a respective gate spacer 108, and a second sloped sidewall contacts and extends along the gate dielectric layer 120.

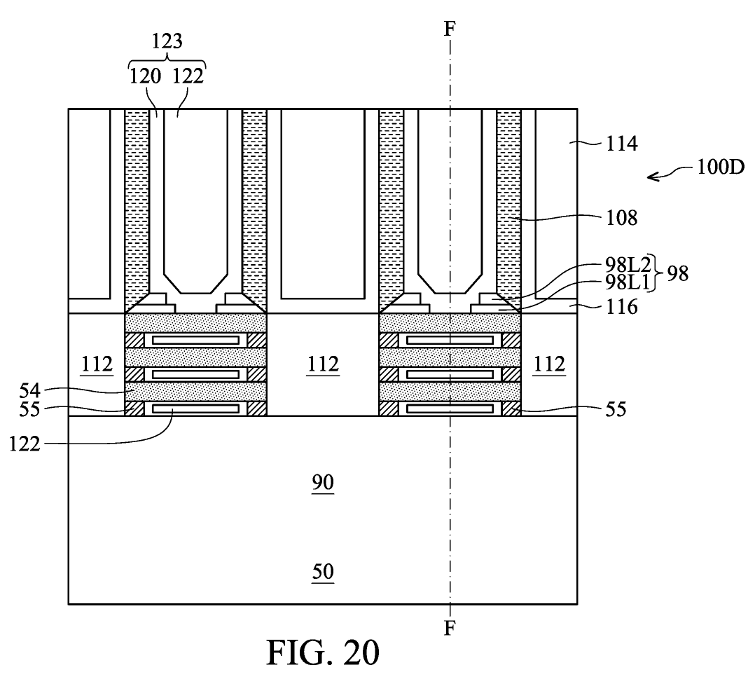

The multi-layered structure of the dielectric structures 98 provides advantages. For example, by choosing different materials with different physical properties (e.g., etch rates), the sidewall profile of the dielectric structures 98 can be controlled/designed to achieve target shapes for different design considerations and/or performance requirements. For example, the layer 98L1 of the first dielectric material may be chosen to have a lower etch rate than the layer 98L2 of the second dielectric material, this may result in the layer 98L1 of the first dielectric material to protrude more from the sidewall of the gate spacer 108. In addition, different material choices may also result in staircase-shaped sidewalls instead of sloped sidewalls (e.g., sloped, linear sidewalls). An example is given in FIG. 20.

FIG. 20 illustrates a cross-sectional view of an NSFET device 100D, in another embodiment. The NSFET device 100D is similar to the NSFET device 100C, and may be formed by the same or similar formation process for the NSFET device 100C. Each of the dielectric structures 98 of the NSFET device 100D, however, has a staircase-shaped sidewall facing a respective replacement gate structure 123. The other sidewall of the dielectric structure 98 of the NSFET device 100D is a sloped sidewall (e.g., a sloped, linear sidewall). In other embodiments, both sidewalls of the dielectric structure 98 of the NSFET device are staircase-shaped sidewalls. Besides staircase-shaped sidewalls, other shapes for the sidewalls are also possible and are fully intended to be included within the scope of the present disclosure.

Embodiments may achieve advantages. By forming dielectric structures with high etching resistance (e.g., low etch rate) at bottom corner regions of the gate trenches, the disclosed methods prevent metal gate extrusion and/or electrical short between the metal gate and the source/drain regions. The trimming of the gate spacers increases the widths of the gate trenches, which not only makes it easier to form replacement gate structures in the gate trenches, but also reduces the electrical resistance of the replacement gate structures. The use of sacrificial material in the DIO process prevents intermixing between silicon and germanium, thus avoiding product defects and improving production yield.

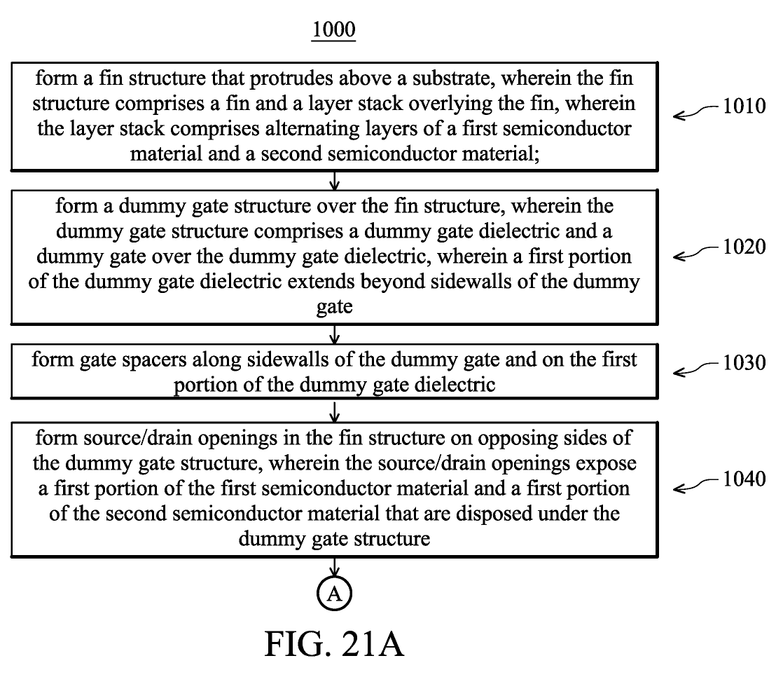

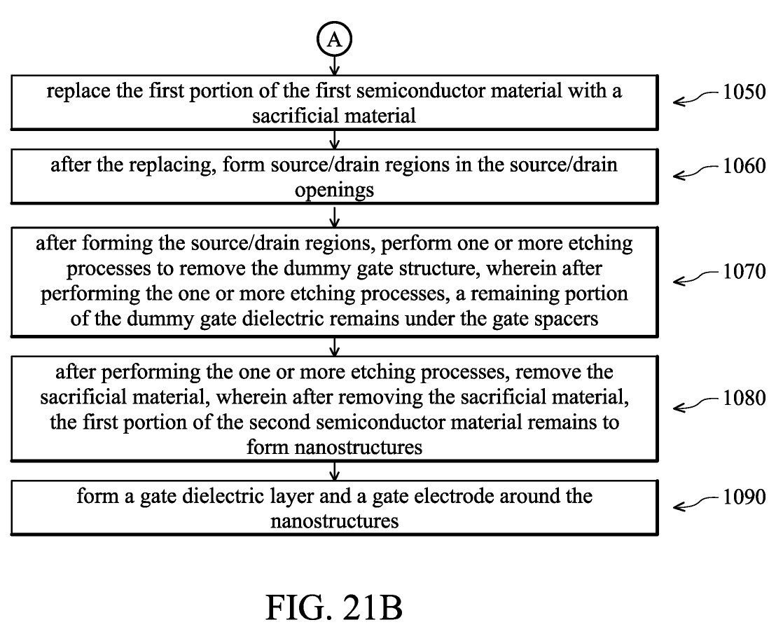

FIGS. 21A and 21B together illustrates a flow chart of a method 1000 of forming a semiconductor device, in accordance with some embodiments. It should be understood that the embodiment method shown in FIGS. 21A and 21B is merely an example of many possible embodiment methods. One of ordinary skill in the art would recognize many variations, alternatives, and modifications. For example, various steps as illustrated in FIGS. 21A and 21B may be added, removed, replaced, rearranged, or repeated.

Referring to FIGS. 21A and 21B, at block 1010, a fin structure that protrudes above a substrate is formed, wherein the fin structure comprises a fin and a layer stack overlying the fin, wherein the layer stack comprises alternating layers of a first semiconductor material and a second semiconductor material. At block 1020, a dummy gate structure is formed over the fin structure, wherein the dummy gate structure comprises a dummy gate dielectric and a dummy gate over the dummy gate dielectric, wherein a first portion of the dummy gate dielectric extends beyond sidewalls of the dummy gate. At block 1030, gate spacers are formed along sidewalls of the dummy gate and on the first portion of the dummy gate dielectric. At block 1040, source/drain openings are formed in the fin structure on opposing sides of the dummy gate structure, wherein the source/drain openings expose a first portion of the first semiconductor material and a first portion of the second semiconductor material that are disposed under the dummy gate structure. At block 1050, the first portion of the first semiconductor material is replaced with a sacrificial material. At block 1060, after the replacing, source/drain regions are formed in the source/drain openings. At block 1070, after forming the source/drain regions, one or more etching processes are performed to remove the dummy gate structure, wherein after performing the one or more etching processes, a remaining portion of the dummy gate dielectric remains under the gate spacers. At block 1080, after performing the one or more etching processes, the sacrificial material is removed, wherein after removing the sacrificial material, the first portion of the second semiconductor material remains to form nanostructures. At block 1090, a gate dielectric layer and a gate electrode are formed around the nanostructures.

In an embodiment, a method of forming a semiconductor device includes: forming a fin structure that protrudes above a substrate, wherein the fin structure comprises a fin and a layer stack overlying the fin, wherein the layer stack comprises alternating layers of a first semiconductor material and a second semiconductor material; forming a dummy gate structure over the fin structure, wherein the dummy gate structure comprises a dummy gate dielectric and a dummy gate over the dummy gate dielectric, wherein a first portion of the dummy gate dielectric extends beyond sidewalls of the dummy gate; forming gate spacers along sidewalls of the dummy gate and on the first portion of the dummy gate dielectric; forming source/drain openings in the fin structure on opposing sides of the dummy gate structure, wherein the source/drain openings expose a first portion of the first semiconductor material and a first portion of the second semiconductor material that are disposed under the dummy gate structure; replacing the first portion of the first semiconductor material with a sacrificial material; after the replacing, forming source/drain regions in the source/drain openings; after forming the source/drain regions, performing one or more etching processes to remove the dummy gate structure, wherein after performing the one or more etching processes, a remaining portion of the dummy gate dielectric remains under the gate spacers; after performing the one or more etching processes, removing the sacrificial material, wherein after removing the sacrificial material, the first portion of the second semiconductor material remains to form nanostructures; and forming a gate dielectric layer and a gate electrode around the nanostructures. In an embodiment, the gate dielectric layer contacts and extends along a surface of the remaining portion of the dummy gate dielectric facing the gate electrode. In an embodiment, the dummy gate dielectric is formed of silicon oxycarbide, silicon oxynitride, silicon carbonitride, or silicon oxycarbonitride. In an embodiment, the dummy gate dielectric is formed of a high-K dielectric material. In an embodiment, the method further comprises, after the replacing and before forming the source/drain regions: recessing the sacrificial material from respective sidewalls of the first portion of the second semiconductor material to form sidewall recesses in the sacrificial material; and forming inner spacers in the sidewall recesses. In an embodiment, performing one or more etching processes comprises: performing a first etching process to remove the dummy gate, wherein a second portion of the dummy gate dielectric under the dummy gate is exposed after the first etching process; and after performing the first etching process, trimming the gate spacers to reduce a thickness of the gate spacers, wherein the trimming removes the second portion of the dummy gate dielectric. In an embodiment, the trimming further removes regions of the first portion of the dummy gate dielectric exposed by the gate spacers with reduced thickness. In an embodiment, trimming the gate spacers comprises: treating the gate spacers with a plasma process; and after the treating, etching the gate spacers by performing a second etching process different from the first etching process. In an embodiment, the plasma process is performed using a gas source comprising oxygen. In an embodiment, forming the dummy gate structure comprises forming the dummy gate dielectric with a multi-layered structure, wherein the dummy gate dielectric is formed to include: a layer of a first dielectric material; and a layer of a second dielectric material over the layer of the first dielectric material. In an embodiment, the first dielectric material has a lower etch rate than the second dielectric material.

In an embodiment, a method of forming a semiconductor device includes: forming a fin structure that protrudes above a substrate, wherein the fin structure comprises a fin and a layer stack over the fin, wherein the layer stack comprises layers of a first semiconductor material interleaved with layers of a second semiconductor material; forming a dummy gate dielectric over the fin structure; forming a dummy gate over the dummy gate dielectric, wherein the dummy gate dielectric extends beyond sidewalls of the dummy gate; forming a gate spacer along a sidewall of the dummy gate and on the dummy gate dielectric; forming a source/drain opening in the fin structure adjacent to the gate spacer; replacing the first semiconductor material disposed under the dummy gate with a sacrificial material; after the replacing, forming a source/drain region in the source/drain opening; after forming the source/drain region, performing a first etching process to remove the dummy gate; after performing the first etching process, performing a second etching process to remove the dummy gate dielectric, wherein after the second etching process, a portion of the dummy gate dielectric remains under the gate spacer; and after performing the second etching process, removing the sacrificial material. In an embodiment, removing the sacrificial material comprises performing a selective etching process to remove the sacrificial material, wherein after the selective etching process, the second semiconductor material previously disposed under the dummy gate remains and forms a plurality of nanostructures. In an embodiment, the method further comprises: forming a gate dielectric material around the plurality of nanostructures; and forming a gate electrode material around the gate dielectric material. In an embodiment, the method further comprises, after performing the first etching process and before performing the second etching process, treating the gate spacer with a plasma process. In an embodiment, treating the gate spacer with the plasma process increases a concentration of oxygen in the gate spacer, wherein the second etching process further reduces a thickness of the gate spacer.

In an embodiment, a semiconductor device includes: a substrate; a fin protruding above the substrate; a gate structure over the fin; a gate spacer extending along a sidewall of the gate structure; source/drain regions over the fin on opposing sides of the gate structure; nanostructures between the source/drain regions and under the gate structure; and a dielectric structure between the gate spacer and the nanostructures, wherein an upper portion of the dielectric structure extends between a lower surface of the gate spacer facing the substrate and an upper surface of a topmost nanostructure of the nanostructures distal from the substrate. In an embodiment, the gate structure comprises a gate dielectric layer around the nanostructures, and a gate electrode around the gate dielectric layer, wherein the gate dielectric layer contacts and extends along a first sidewall of the upper portion of the dielectric structure facing the gate electrode. In an embodiment, the lower surface of the gate spacer contacts and extends along a second opposing sidewall of the upper portion of the dielectric structure. In an embodiment, the dielectric structure comprises: a layer of a first dielectric material; and a layer of a second dielectric material different from the first dielectric material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a fin protruding above the substrate;
channel layers vertically stacked over the fin;
a gate structure over the fin and around the channel layers, wherein the gate structure comprises a gate dielectric layer and a gate electrode;
source/drain regions over the fin on opposing sides of the gate structure;
a gate spacer extending along a sidewall of the gate structure; and
a dielectric structure interposed between the gate spacer and the channel layers, wherein the dielectric structure extends along an upper surface of an uppermost channel layer of the channel layers distal from the substrate, and along sidewalls of the channel layers, wherein an upper portion of the dielectric structure is disposed between a lower surface of the gate spacer facing the substrate and the upper surface of the uppermost channel layer.

2. The semiconductor device of claim 1, wherein the upper portion of the dielectric structure has a lower surface contacting the upper surface of the uppermost channel layer and has a first sidewall contacting the lower surface of the gate spacer, wherein the first sidewall is a sloped sidewall.

3. The semiconductor device of claim 2, wherein the upper portion of the dielectric structure has a second sidewall opposing the first sidewall, wherein the gate dielectric layer contacts the second sidewall.

4. The semiconductor device of claim 3, wherein the second sidewall is another sloped sidewall, wherein the second sidewall extends toward the gate structure beyond a sidewall of the gate spacer facing the gate structure.

5. The semiconductor device of claim 4, wherein the first sidewall and the second sidewall intersect at the sidewall of the gate spacer facing the gate structure.

6. The semiconductor device of claim 3, wherein the second sidewall is a straight sidewall that is flush with a sidewall of the gate spacer facing the gate structure.

7. The semiconductor device of claim 3, wherein the second sidewall is a curved sidewall that is recessed from a sidewall of the gate spacer facing the gate structure, wherein the gate structure comprises a protrusion that extends under the gate spacer and contacts the curved sidewall.

8. The semiconductor device of claim 3, wherein the dielectric structure has a multi-layered structure, wherein a first sublayer of the dielectric structure is in contact with the channel layers, and a second sublayer of the dielectric structure is between the first sublayer and the gate spacer, wherein the first sublayer and the second sublayer comprise different dielectric materials.

9. The semiconductor device of claim 8, wherein the second sidewall has a staircase shape, wherein each of the first sublayer and the second sublayer corresponds to a respective stair of the staircase shape.

10. The semiconductor device of claim 8, wherein the second sidewall is another sloped sidewall, wherein the first sidewall and the second sidewall intersect at a sidewall of the gate spacer facing the gate structure.

11. A semiconductor device comprising:
a substrate;
a fin protruding above the substrate;
nanostructures over the fin and vertically spaced apart from one another;
a gate structure over the fin and around the nanostructures, wherein the gate structure comprises a gate dielectric layer and a gate electrode over the gate dielectric layer;
source/drain regions over the fin on opposing sides of the gate structure;
a gate spacer extending along a sidewall of the gate structure, wherein the gate spacer has a sloped lower surface facing the substrate; and
a dielectric structure disposed laterally between the gate spacer and the gate structure, wherein the dielectric structure has a first sidewall and a second sidewall that intersect each other, wherein the first sidewall extends along the sloped lower surface of the gate spacer, and the second sidewall extends along the gate dielectric layer.

12. The semiconductor device of claim 11, wherein the first sidewall and the second sidewall are sloped sidewalls, wherein the first sidewall and the second sidewall intersect at an inner sidewall of the gate spacer facing the gate structure.

13. The semiconductor device of claim 11, wherein the first sidewall is a sloped sidewall, and the second sidewall is a staircase-shaped sidewall.

14. The semiconductor device of claim 11, wherein the dielectric structure has a multi-layered structure that includes a first sublayer and a second sublayer over the first sublayer, wherein the first sublayer and the second sublayer comprise different dielectric materials, wherein the first sublayer contacts an uppermost nanostructure of the nanostructures and extends laterally further from an inner sidewall of the gate spacer facing the gate structure than the second sublayer.

15. The semiconductor device of claim 11, wherein the first sidewall is a sloped sidewall, and the second sidewall is a concave sidewall that is recessed from an inner sidewall of the gate spacer facing the gate structure.

16. The semiconductor device of claim 11, wherein the first sidewall is a sloped sidewall, and the second sidewall is a straight sidewall that is flush with an inner sidewall of the gate spacer facing the gate structure.

17. A method of forming a semiconductor device, the method comprising:
forming a fin structure protruding above a substrate, wherein the fin structure comprises a fin and a layer stack over the fin, the layer stack comprising layers of a first semiconductor material interleaved with layers of a second semiconductor material;
forming a dummy gate structure over the fin structure, wherein the dummy gate structure comprises a dummy gate dielectric and a dummy gate over the dummy gate dielectric, wherein the dummy gate dielectric is wider than the dummy gate such that a first portion of the dummy gate dielectric is disposed under the dummy gate, and a second portion of the dummy gate dielectric extends laterally beyond sidewalls of the dummy gate;
forming gate spacers along the sidewalls of the dummy gate and on the second portion of the dummy gate dielectric;
forming source/drain openings in the fin structure on opposing sides of the dummy gate;
replacing the first semiconductor material disposed under the dummy gate with a sacrificial material;
after the replacing, forming source/drain regions in the source/drain openings;
after forming the source/drain regions, removing the dummy gate to form a gate trench between the gate spacers, wherein the first portion of the dummy gate dielectric is exposed at a bottom of the gate trench;
etching the exposed first portion of the dummy gate dielectric with an etching process, wherein the etching process removes the first portion of the dummy gate dielectric from a center region of the gate trench, wherein after the etching process is completed, a remaining portion of the first portion of the dummy gate dielectric adjacent to the gate spacers and the second portion of the dummy gate dielectric form dielectric structures;
after the etching process, removing the sacrificial material to release the second semiconductor material as nanostructures; and
forming a replacement gate structure in the gate trench and around the nanostructures.

18. The method of claim 17, wherein the second portion of the dummy gate dielectric has sloped sidewalls, wherein the gate spacers are formed to have sloped lower surfaces contacting the sloped sidewalls of the second portion of the dummy gate dielectric.

19. The method of claim 17, wherein the replacement gate structure comprises a gate dielectric layer and a gate electrode, wherein the gate dielectric layer contacts and extends along the dielectric structures.

20. The method of claim 17, wherein the dummy gate dielectric is formed to have a multi-layered structure that includes a plurality of sublayers comprising different dielectric materials, wherein the dielectric structures have the multi-layered structure.
